(19) United States
(12) Patent Application Publication
(10) Pub. No.: US 2026/0173828 A1
(43) Pub. Date: Jun. 18, 2026

(54) MANUFACTURING METHOD OF SEMICONDUCTOR STRUCTURE

(71) Applicant: NANYA TECHNOLOGY CORPORATION, New Taipei City (TW)

(72) Inventors: Li Han Lin, New Taipei City (TW); Chang-Ju Chien, New Taipei City (TW)

(73) Assignee: NANYA TECHNOLOGY CORPORATION, New Taipei City (TW)

(21) Appl. No.: 18/986,657

(22) Filed: Dec. 18, 2024

(51) Int. Cl. H01L 21/321; H01L 21/768

(52) U.S. Cl. CPC H10P 95/00; H10W 20/081

(57) ABSTRACT

A manufacturing method of a semiconductor structure is provided. The method includes the following steps. A conductive layer is formed on a substrate. A protection layer is formed on the conductive, wherein the protection layer includes a plurality of first pores, and the first pores expose portions of the conductive layer. A nitridation treatment is performed on the exposed portions of the conductive layer through the first pores to form nitride portions at a top surface of the conductive layer. A dielectric layer is formed on the protection layer, wherein the dielectric layer includes a plurality of second pores. A clean treatment is performed on the dielectric layer.

### BACKGROUND

### Technical Field

The present invention relates to a semiconductor process, and in particular to a manufacturing method of a semiconductor structure including a conductive layer, which may prevent the conductive layer from being damaged by water from the outside.

### Description of Related Art

In current semiconductor processes, after forming a conductive layer on a substrate, a dielectric layer is formed on the substrate to cover the conductive layer. In addition, in subsequent processes, a clean treatment may be performed on the dielectric layer to remove residues or contaminants on the surface of the dielectric layer.

During the cleaning process, water used as the cleaning solution is not only distributed on the surface of the dielectric layer, but also reaches the surface of the conductive layer through the pores in the dielectric layer. When the cleaning solution contacts the conductive layer, the conductive layer may be corroded, causing the electrical properties of the conductive layer to be affected.

### SUMMARY

The present invention provides a manufacturing method of a semiconductor structure including a conductive layer, in which the conductive layer is subjected to a nitridation treatment after a protection layer is formed on the conductive layer.

The manufacturing method of the semiconductor structure of the present invention includes the following steps. A conductive layer is formed on a substrate. A protection layer is formed on the conductive, wherein the protection layer includes a plurality of first pores, and the first pores expose portions of the conductive layer. A nitridation treatment is performed on the exposed portions of the conductive layer through the first pores to form nitride portions at a top surface of the conductive layer. A dielectric layer is formed on the protection layer, wherein the dielectric layer includes a plurality of second pores. A clean treatment is performed on the dielectric layer.

In an embodiment of the manufacturing method of the semiconductor structure of the present invention, the nitridation treatment is performed by using a mixed gas of hydrogen and nitrogen.

In an embodiment of the manufacturing method of the semiconductor structure of the present invention, a cleaning solution used in the clean treatment includes water.

In an embodiment of the manufacturing method of the semiconductor structure of the present invention, the cleaning solution reaches the nitride portions of the conductive layer through the first pores and the second pores.

In an embodiment of the manufacturing method of the semiconductor structure of the present invention, a material of the conductive layer includes metal.

In an embodiment of the manufacturing method of the semiconductor structure of the present invention, a material of the protection layer includes nitride.

In an embodiment of the manufacturing method of the semiconductor structure of the present invention, a thickness of the protection layer does not exceed 200 nm.

In an embodiment of the manufacturing method of the semiconductor structure of the present invention, a material of the dielectric layer includes oxide.

In an embodiment of the manufacturing method of the semiconductor structure of the present invention, a thickness of the dielectric layer does not exceed 200 nm.

In an embodiment of the manufacturing method of the semiconductor structure of the present invention, the substrate includes a dielectric substrate.

Based on the above, in the manufacturing method of the semiconductor structure of the present invention, after the protection layer is formed on the conductive layer, the conductive layer is subjected to a nitridation treatment to form nitride portions through the pores in the protection layer. Therefore, in the subsequent cleaning treatment, even if the cleaning solution penetrate through the protection layer through the pores, due to the existence of the nitride portions, the conductive layer may not be corroded by the cleaning solution.

### BRIEF DESCRIPTION OF THE DRAWINGS

FIGS. 1A to 1C are schematic cross-sectional views of the manufacturing method of the semiconductor structure of the embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

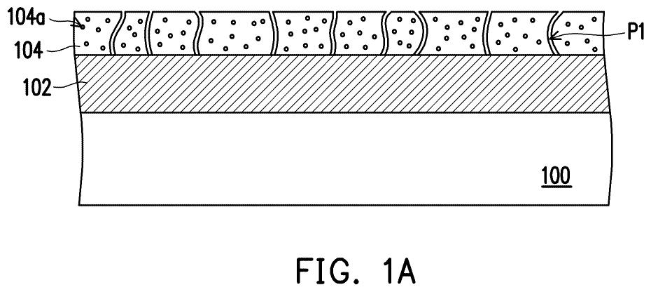

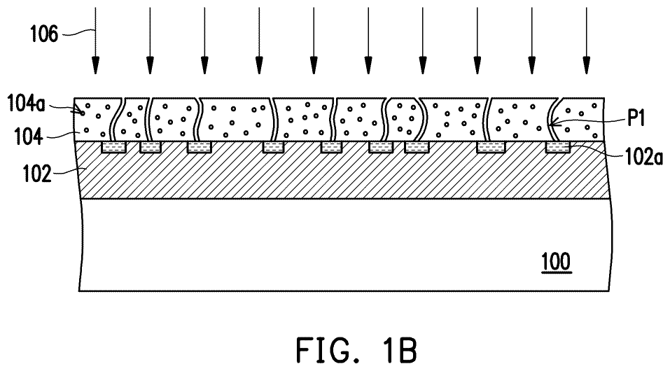

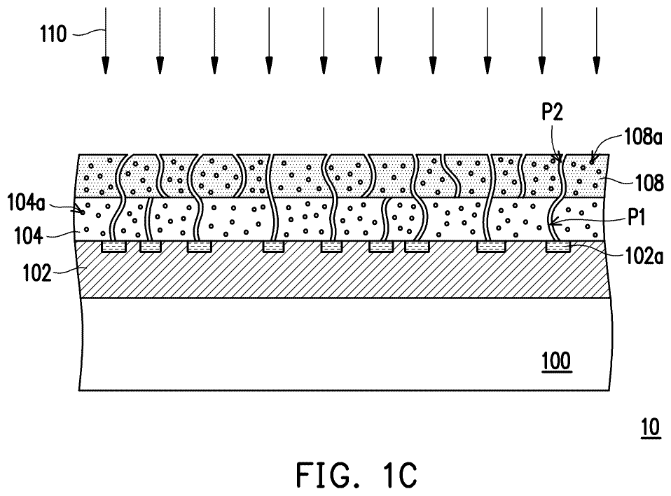

FIGS. 1A to 1C are schematic cross-sectional views of the manufacturing method of the semiconductor structure of the embodiment of the present invention.

Referring to FIG. 1A, a substrate 100 is provided. In the present embodiment, the substrate 100 may be a dielectric substrate, but the present invention is not limited thereto. For example, in one embodiment, the substrate 100 may be a dielectric layer formed on a silicon substrate. Then, a conductive layer 102 may be formed on the substrate 100. The material of the conductive layer 102 may be metal. For example, the material of the conductive layer 102 may be tungsten (W), but the present invention is not limited thereto. In one embodiment, the conductive layer 102 may be used to form a gate of a transistor or a control gate of a memory cell, but the present invention is not limited thereto.

For the conductive layer 102 including metal, when the conductive layer 102 is in contact with water in the subsequent processes, the conductive layer 102 may be corroded and thus the electrical properties of the conductive layer 102 may be affected. Therefore, in the present embodiment, a protection layer 104 may be formed on the conductive layer 102. The protection layer 104 may be used to prevent the conductive layer 102 from being contact with large amounts of water from outside. In addition, the protection layer 104 may have a greater hardness to prevent the conductive layer 102 from being damaged in subsequent processes. In the present embodiment, the protection layer 104 may be a dielectric layer. For example, the material of the protection layer 104 may be nitride, but the present invention is not limited thereto.

In addition, based on the material of the protection layer 104, the protection layer 104 inevitably includes a plurality of first pores 104a, and the first pores 104a at the bottom of the protection layer 104 expose portions of the conductive layer 102. As a result, in the protection layer 104, some first pores 104a connected with each other may form paths P1 connected to the outside.

In addition, in the present embodiment, the thickness of the protection layer 104 does not exceed 200 nm. If the thickness of the protection layer 104 exceeds 200 nm, the protection layer 104 is too thick, causing the subsequent etching process on the protection layer 104 to be affected.

Referring to FIG. 1B′ a nitridation treatment 106 is performed on the exposed portions of the conductive layer 102. In detail, the nitridation treatment 106 is performed by using a nitrogen-containing gas, such as a mixed gas of hydrogen and nitrogen. The nitrogen-containing gas may penetrate through the protection layer 104 to contact the exposed portions of the conductive layer 102 through the paths P1 formed by the first pores 104a connected with each other. When the nitrogen-containing gas contacts the exposed portions of the conductive layer 102, the exposed portions of the conductive layer 102 may be nitrided by nitrogen in the nitrogen-containing gas to form nitride portions 102a at the top surface of the conductive layer 102. Compared with the material of the conductive layer 102, the nitride portions 102a do not react with water, and thus may not be corroded after being in contact with water.

Referring to FIG. 1C, a dielectric layer 108 is formed on the protection layer 104. The material of the dielectric layer 108 may be oxide. Based on the material of the dielectric layer 108, the dielectric layer 108 inevitably includes a plurality of second pores 108a, and the second pores 108a at the bottom of the dielectric layer 108 expose portions of the protection layer 104. As a result, in the dielectric layer 108, the second pores 108a connected with each other may form paths P2 connected to the outside. In this way, some of the second pores 108a at the bottom of the dielectric layer 108 may be connected with some of the first pores 104a at the top of the protection layer 104, so that some of the paths P2 may be connected to some of the paths P1.

In addition, in the present embodiment, the thickness of the dielectric layer 108 does not exceed 200 nm. If the thickness of the dielectric layer 108 exceeds 200 nm, the dielectric layer 108 is too thick, causing the subsequent etching process on the dielectric layer 108 to be affected.

After forming the dielectric layer 108, in the subsequent process, a clean treatment 108 may be performed on the dielectric layer 108 to remove residues or contaminants on the dielectric layer 108. The cleaning solution used in the clean treatment 110 may be water. In this way, the semiconductor structure 10 of the present embodiment is formed.

During the clean treatment 110, in addition to being distributed on the top surface of the dielectric layer 108, the cleaning solution may penetrate through the dielectric layer 108 and the protection layer 104 through the paths P1 and the path P2 connected to each other, to reaches the exposed portions of the conductive layer 102. In the present embodiment, since the exposed portions of the conductive layer 102 have been nitrides to the nitride portions 102a, the exposed portions of the conductive layer 102 may not be corroded by the cleaning solution. Therefore, after the clean treatment 110, the conductive layer 102 may not be damaged.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a semiconductor structure, comprising:
forming a conductive layer on a substrate;
forming a protection layer on the conductive, wherein the protection layer comprises a plurality of first pores, and the first pores expose portions of the conductive layer;
performing a nitridation treatment on the exposed portions of the conductive layer through the first pores to form nitride portions at a top surface of the conductive layer;
forming a dielectric layer on the protection layer, wherein the dielectric layer comprises a plurality of second pores; and
performing a clean treatment on the dielectric layer.

2. The manufacturing method of claim 1, wherein the nitridation treatment is performed by using a mixed gas of hydrogen and nitrogen.

3. The manufacturing method of claim 1, wherein a cleaning solution used in the clean treatment comprises water.

4. The manufacturing method of claim 3, wherein the cleaning solution reaches the nitride portions of the conductive layer through the first pores and the second pores.

5. The manufacturing method of claim 1, wherein a material of the conductive layer comprises metal.

6. The manufacturing method of claim 1, wherein a material of the protection layer comprises nitride.

7. The manufacturing method of claim 1, wherein a thickness of the protection layer does not exceed 200 nm.

8. The manufacturing method of claim 1, wherein a material of the dielectric layer comprises oxide.

9. The manufacturing method of claim 1, wherein a thickness of the dielectric layer does not exceed 200 nm.

10. The manufacturing method of claim 1, wherein the substrate comprises a dielectric substrate.
